(19) United States
(12) Patent Application Publication
(10) Pub. No.: US 2007/0148597 A1
(43) Pub. Date: Jun. 28, 2007

(54) Method and apparatus for laser exposure of a screen for use in screen printing

(76) Inventor: Josef Lindthaler, Bad Oeynhausen (DE)

Correspondence Address: THOMAS R. VIGIL, 221 N. STATE STREET, ROOM 2036, CHICAGO, IL, 60601, US

(21) Appl. No.: 11/643,602

(22) Filed: Dec. 21, 2006

(30) Foreign Application Priority Data
Dec. 24, 2005 (DE) 10 2005 062 217.8
Dec. 24, 2005 (DE) 20 2005 020 198.7

(51) Int. Cl. G03F 7/12

(52) U.S. Cl. 430/308

(57) ABSTRACT

The subject matter of the invention is a method for laser exposure of a screen (11), whereas only one portion of the screen (11) is used for motive exposure (16). Providing a method for laser exposure of a screen of the type mentioned herein above, in which soiling of the screen printing apparatus is prevented without high costs is achieved by also exposing a margin region (18) of the screen (11) located outside the motive exposure area (16).

This application claims Priority from German Applications No. DE 10 2005 062 217.8-51 filed on Dec. 24, 2005 and DE 20 2005 020 198.7 filed on Dec. 24, 2005

### BACKGROUND OF THE INVENTION

1. Field of the Invention

The present invention relates to a method according to the preamble of claim 1 and to an apparatus according to the preamble of claim 8.

In screen printing with laser-exposed screens, the actual image, the so-called motive exposure area, is usually disposed in the center of the screen. For this purpose, the region of concern is covered with a light-sensitive emulsion and then a negative of the image wanted is projected thereon. In the exposed areas, the emulsion binds durably with the screen and remains there. The rest of the emulsion is then removed.

The screen is dimensioned so as to be significantly larger than the actual motive exposure area so that images of different sizes can be applied and that sufficient space is provided for ink application during subsequent screen printing. It happens that the ink inadvertently passes through the screen in the margin region lying outside of the motive exposure area, thus soiling the entire screen printing apparatus. To prevent this from happening, the unexposed margin region is tediously covered, in a separate step with an ink impermeable screen filler preventing ink from passing in the margin region.

2. Description of the Prior Art

It is known from the document GB 1 517 291 A to provide the screen with a light-sensitive adhesive, the region outside of motive exposure area also being exposed to light in order to fix said adhesive to the screen.

It is known from the document EP 0 246 741 A2 to provide the entire screen with a photosensitive emulsion that cures after exposure except in the region of the useful exposure area.

In the two printed documents mentioned, the screen is exposed to conventional light sources, not to laser light. There is the risk that the actual motive exposure area may be affected by scattered light. Moreover, such an exposure is very expensive both in terms of cost and time.

### BRIEF SUMMARY OF THE INVENTION

In view thereof, the object of the present invention is to provide a method and an apparatus for laser exposure of a screen of the type mentioned herein above in which the margins are exposed much faster and at much lower cost in order to avoid soiling of the screen printing apparatus.

As a technical solution to this object, the invention proposes a method having the features of claim 1 and an apparatus having the features of claim 8. Advantageous developed implementations of this method and of this apparatus will become apparent in the respective dependent claims.

A method implemented according to this technical teaching and an apparatus implemented according to this technical teaching have the advantage that, by also exposing the margin region of the screen, this part of the screen outside of the motive exposure area is also provided with an ink impermeable coating by exposing the emulsion applied thereon, so that the entire screen is filled. As a result, no ink will be allowed to pass through the screen outside of the motive exposure area so that inadvertent soiling of the system is avoided. Consequently, there is no longer any need to separately apply a screen filler, which brings a significant cost saving.

The exposure of the margins is thereby performed by means of a light bar equipped with a number of diodes, whereas motive exposure is performed using a prior art laser exposer. The advantage thereof is that the much cheaper light bar exposes the margins whilst the very expensive laser exposer is used for motive exposure only. Accordingly, the margins are exposed at very low cost.

It has been found advantageous to expose this margin region so completely, meaning with sufficient intensity, that the emulsion applied in the margin region forms an ink impermeable coating in the fully exposed condition.

Another advantage is that the light bar has a much higher light output than the laser exposer so that the margins can be exposed much faster. Accordingly, the processing of one single screen can be performed in far less time, which lowers the machine and processing costs.

In an advantageous developed implementation, the diodes can be activated individually. This makes it possible to fully expose discrete portions of the margin region without exposing other portions of the screen.

In a particularly preferred embodiment, the light bar and the laser exposer take turns in exposing the screen. The advantage thereof is that motive exposure and margin exposure can be performed in one step.

In an advantageous embodiment, the light bar accommodates a number of UV LEDs, diodes or other light sources. Between 10 and 200, ideally 54, such LEDs are preferably utilized in order for the screen to be exposed across its entire width. These very cheap LEDs, diodes or other light sources can be individually replaced in case of failure, which keeps the operating and repair costs low. The number of UV LEDs, diodes or other light sources depends on the desired angle of reflection, the light efficiency and the luminous power needed to cure the screen.

In a particularly preferred embodiment, the light bar is surrounded by a light impermeable housing that is light permeable toward the screen. This prevents the light bar from emitting scattered light which might damage a possibly already performed motive exposure. Scattered light is in particular minimized by the fact that the housing is brought as close as possible to the screen, it being preferred that

To increase the luminous power and the homogeneity, it is advantageous to configure the inner side of the housing to be reflective.

In dimensioning the housing, it has been found advantageous to configure the permeable opening in such a manner that an outlet port of between 10° and 15°, preferably of 12° be formed. This allows achieving sufficient exposure without unnecessary scattered light. At this angle, the advance speed may also be adjusted so as to be quite high, this allowing to reduce significantly the processing time.

Further advantages of the method of the invention and of the apparatus of the invention will become apparent in the appended drawing and in the following description of embodiments thereof. Likewise, the invention lies in each and every novel feature or combination of features mentioned above or described herein after. The embodiments discussed herein are merely exemplary in nature and are not intended to limit the scope of the invention in any manner.

### BRIEF DESCRIPTION OF THE SEVERAL VIEWS OF THE DRAWING

FIG. 1a-d is a schematic illustration of a first embodiment of margin exposure and of motive exposure of a screen at different instants in time;

FIG. 2a-d is a schematic illustration of a second embodiment of margin exposure and motive exposure of a screen at different instants in time;

FIG. 3a-d is a schematic illustration of a third embodiment of margin exposure and motive exposure of a screen at different instants in time;

FIG. 4 is a schematically illustrated, sectional side view of a fourth embodiment of an apparatus of the invention;

FIG. 5 is a schematically illustrated, sectional side view of a fifth embodiment of an apparatus of the invention.

### DETAILED DESCRIPTION OF THE INVENTION

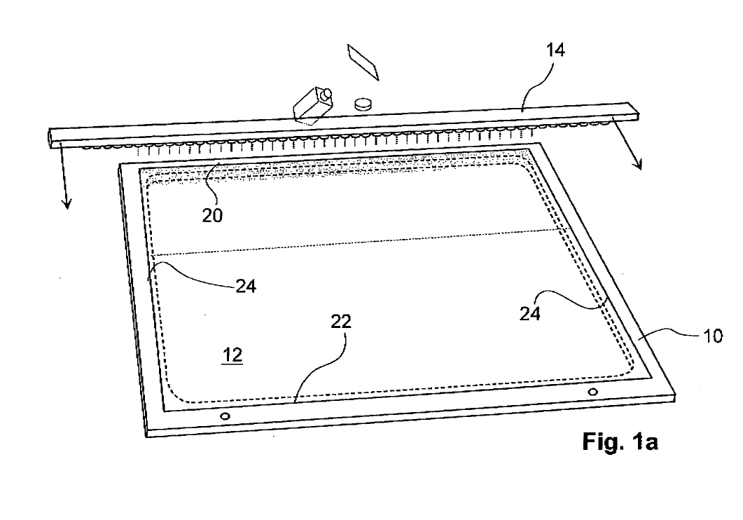

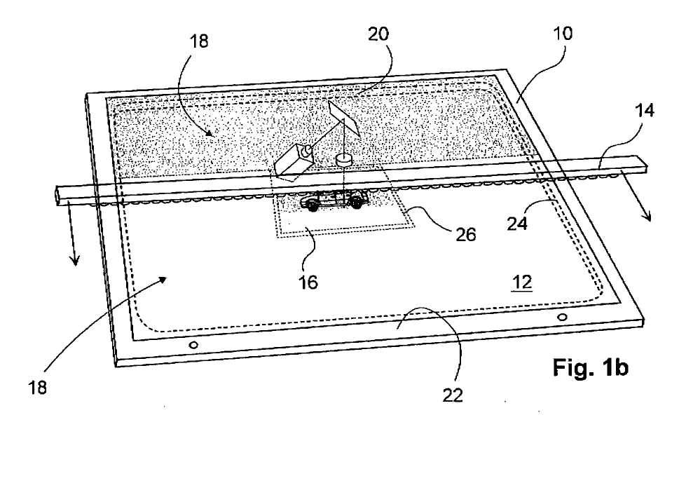

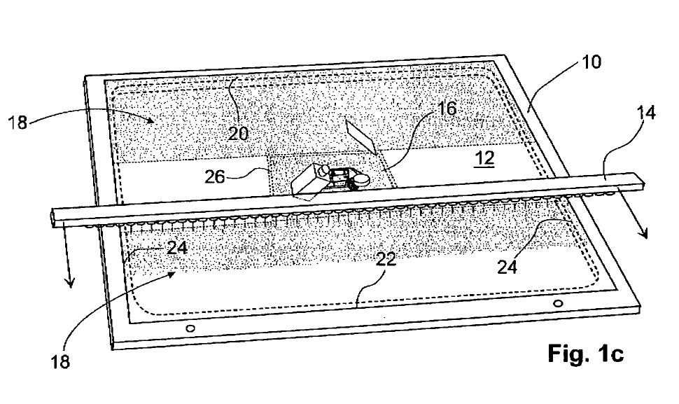

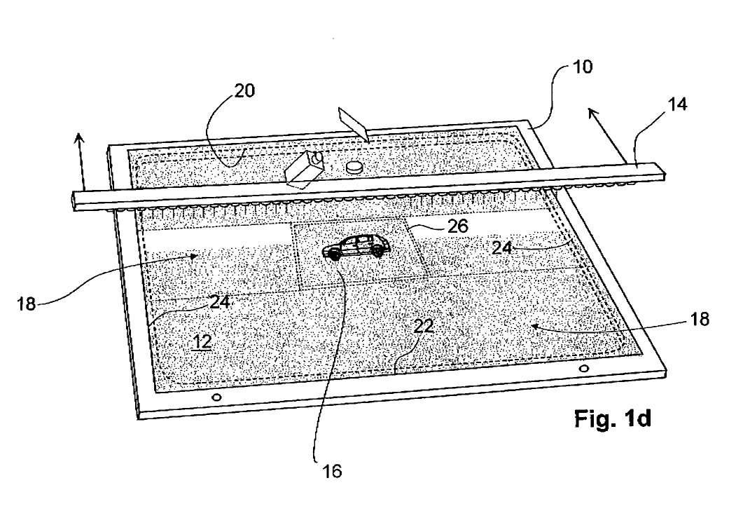

The FIGS. 1a through 1d schematically illustrate a screen 11 prepared with a light sensitive emulsion and held in a frame 10 and across which a laser exposer 12 and a light bar 13 can move. The laser exposer 12 and the light bar 13 are commonly mounted on a movable bridge 14. The light bar 13 is equipped with a number of diodes 15 that are individually activatable. The laser exposer 12 passing across the screen 11 performs motive exposure 16 in the center of the screen 11, whereas the margin region 18 of the screen 11, which is located outside of the motive exposure area 16, also receives exposure from the light bar 13. More specifically:

The bridge 14, together with the laser exposer 12 and the light bar 13 passes across the screen 11 twice (back and forth). The bridge 14 starts at a first edge 20 of the screen 11 and moves towards a second edge 22 of the screen 11, opposite the first edge. While the bridge 14 moves from the first edge 20 to the beginning of the motive exposure area 16, the light bar 13 is switched on and the laser exposer 12 is switched off, as can be seen from FIG. 1a. In this phase, the bridge 14 can move at very high speed since the diodes have sufficient power to sufficiently expose the margin region 18, even if the bridge 14 moves at high speed. Once the edge of the motive exposure area 16 has been reached, the light bar 13 is switched off, the laser exposer 12 is switched on and the speed of the bridge 14 is decelerated for the laser exposer 12 to be able to perform the motive exposure in the known way, as can be seen in FIG. 1b. Upon completion of the motive exposure 16, the laser exposer 12 is switched off again and the light bar 13 switched on in order to fully expose the area of the margin region 18 located between the motive exposure area 16 and a second edge 22 of the screen, as can be seen in FIG. 1c. Again, the bridge 14 moves at high speed.

On its way back, meaning on the second passage over the screen 11, the areas of the margin region 18 between the useful exposure area 16 and the side edges 24 of the screen 12 are fully exposed. Only those diodes 15 are switched on that are arranged above the margin region 18 whilst the diodes disposed above the motive exposure area 16 remain switched off in order to avoid further exposure of the motive exposure area 16, which is not desired.

Next, such an exposed screen 11 is freed in an actually known manner from the non hardened parts of the emulsion so that that portion of the screen is rendered ink impermeable through which no ink should pass later. Since the margin region 18 is now also exposed, this margin region 18 is automatically also provided with the hardened emulsion so that this no longer requires a separate step and that the screen printing apparatus is prevented from being soiled through ink inadvertently passing through the margin region 18.

In the transition area between the motive exposure area 16 and the margin region 18, there is formed what is referred to as a light rim 26 that is exposed both through motive exposure 16 and through margin region exposure 18.

It is understood that the margin region is exposed so strongly that it is finally covered with an ink impermeable coating.

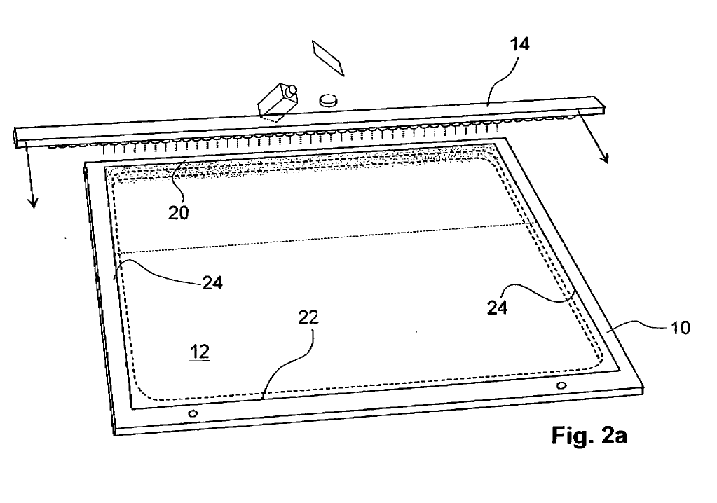

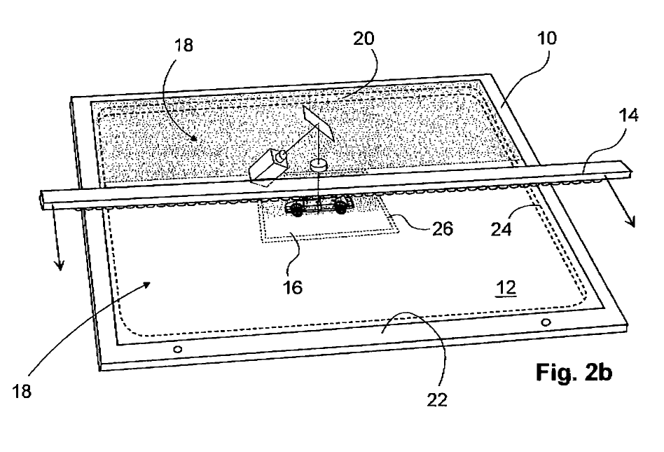

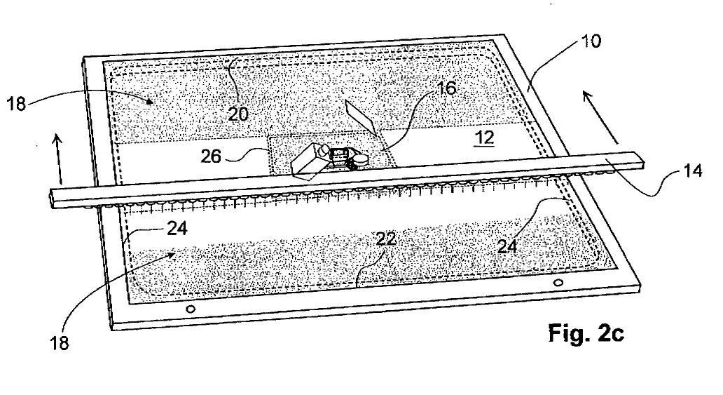

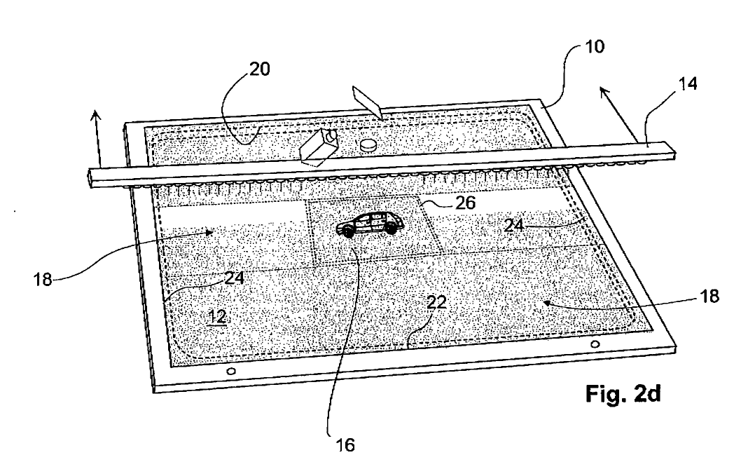

The second embodiment illustrated in the FIGS. 2a through 2d only differs from the first embodiment illustrated in the FIGS. 1a through 1d only by the fact that, once motive exposure 16 is complete, both the light bar 13 and the laser exposer 12 remain switched off and the bridge 14 is quickly moved to the second edge 22 without performing another exposure. The light bar 13 is only activated on the way back, is then exposing the margin region 18 while the bridge 14 is moved back from the second edge 22 to the first edge 20, as can be seen from FIG. 2c.

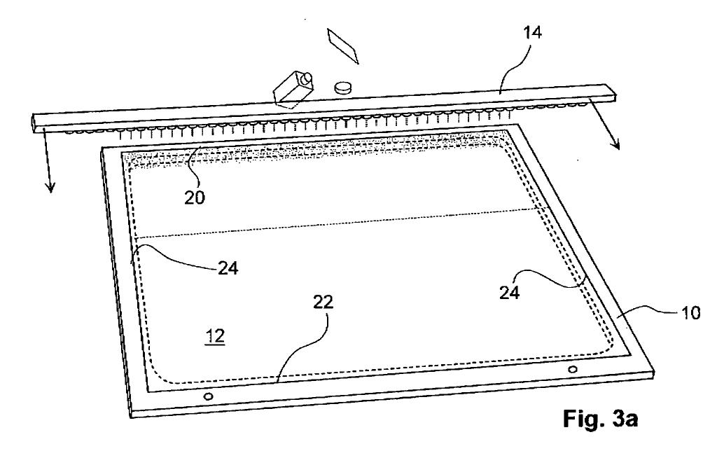

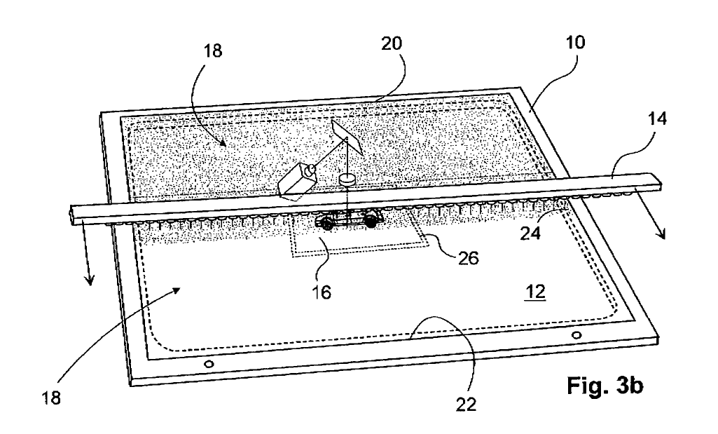

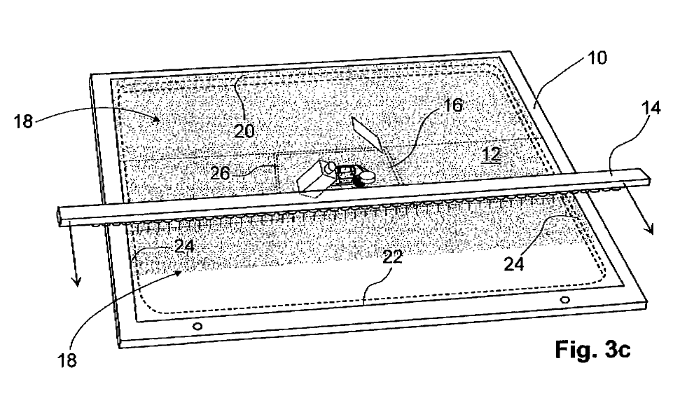

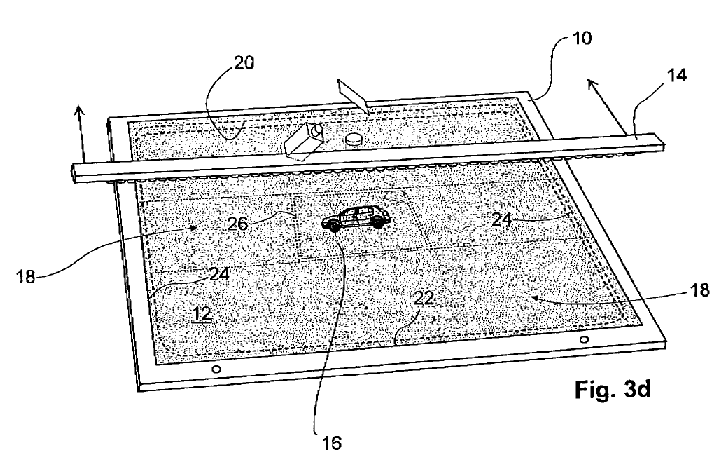

The third embodiment illustrated in the FIGS. 3a through 3d only differs from the first embodiment illustrated in the FIGS. 1a through 1d in that, during motive exposure 16 through the laser exposer 12, some diodes 15 of the light bar 13 are activated as well in order to fully expose the margin region 18 between the motive exposure area 16 and the side edges 24, as can be seen in FIG. 3b. Since during motive exposure 16 the bridge 14 moves at a slower pace than during mere margin exposure 18, the diodes 15 only need to be operated at reduced power in this phase in order to achieve sufficient exposure.

Since in this embodiment both the margin exposure 18 and the motive exposure 16 are completed at the first passage of the screen 11, the bridge 14 may be moved back at higher speed, as can be seen from FIG. 3d.

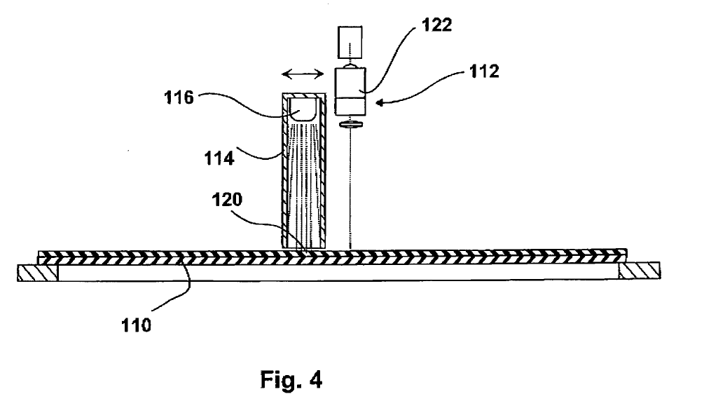

The fourth embodiment shown in FIG. 4 of an apparatus of the invention for exposing a screen for use in screen printing comprises a light bar 112 that is movable across a screen 110 to be exposed. This light bar 112 includes a housing 114 and LEDs 116 that are housed side-by-side along a virtual line 154 in the housing 114 and that are individually activatable.

The housing 114 is light impermeable on three sides and has an approximately 1 mm wide slot 120 on its side turned toward the screen 110. The inner side of the housing 114 is configured to be reflective so that the light emitted by the LEDs is almost completely directed toward the screen 110.

The light bar 112 is mounted directly beside a laser exposer 122 and is moved back and forth across the screen 110 together therewith.

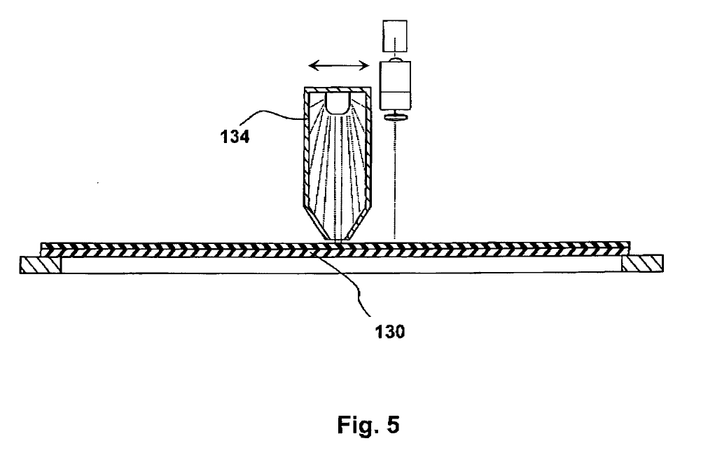

The fifth embodiment illustrated in FIG. 5 only differs from the embodiment illustrated in FIG. 4 by the fact that the housing 134 is configured to conically taper on its side turned toward the screen 130.

In another embodiment that has not been illustrated herein, the light bar is solidly mounted and the screen is accordingly moved back and forth underneath the light bar.

### List of Numerals

10 frame
11 screen
12 laser exposer
13 light bar
14 bridge
15 diodes
16 useful exposure (area)
18 margin region
20 first edge of the screen
22 second edge of the screen
24 side edge
26 light rim
110, 130 screen
112 light bar
114, 134 housing
116 LED
120 slot
122 laser exposer

I claim:

1. A method for laser exposure of a screen (12), whereas only one portion of the screen (12) is used for motive exposure (16),
characterized in that a margin region (18) of the screen (12) located outside the area of the motive exposure (16) is also exposed and that the margin region is exposed by means of a light bar (13) comprising a number of diodes whilst motive exposure is performed by means of an actually known laser exposer (12).

2. The method as set forth in claim 1,
characterized in that the luminous power of the light bar (13) is greater than the luminous power of the laser exposer (12).

3. The method as set forth in claim 1,
characterized in that the diodes (15) are individually activatable.

4. The method as set forth in claim 1,
characterized in that, at first the laser exposer (12) moves together with the light bar (13) across the screen (11), starting from a first edge (20) towards a second edge (22), and then both are caused to move in the reverse direction from the second edge (22) towards the first edge (20), thereby the light bar (13) first exposes the margin region (18) from the first edge (20) to the motive exposure area (16), then the laser exposer (12) is performing a motive exposure (16), next the light bar (13) exposes the margin region (18) from the motive exposure area (16) to the second edge (22), whereas those diodes (15) of the light bar (13) that are arranged above the margin region (18) between the motive exposure area (16) and the side edges (24) are fully exposing said margin region (18) on their way back.

5. The method as set forth in claim 1,
characterized in that, at first the laser exposer (12) moves together with the light bar (13) across the screen (11), starting from a first edge (20) toward a second edge (22) and then both are caused to move in the reverse direction from the second edge (22) towards the first edge (20), thereby the light bar (13) exposes the margin region (18) from the first edge (20) to the motive exposure area (16), then the laser exposer (12) is performing a motive exposure (16), next the light bar (13) and the laser exposer (12) being caused to move to the second edge (22) in the switched off position, while during the second passage over the screen (11) the light bar (13) is switched on starting from the second edge (22) to fully expose the margin region (18) from the second edge (22) to the motive exposure area (16), whereas those diodes (15) of the light bar (13) that are arranged above the margin region (18) between the motive exposure area (16) and the side edges (24) are fully exposing said margin region (18) on their way back.

6. The method as set forth in claim 1,
characterized in that, at first the laser exposer (12) moves together with the light bar (13) across the screen (11), starting from a first edge (20) towards a second edge (22) and then both are caused to move in the reverse direction from the second edge (22) towards the first edge (20), thereby the light bar (13) first exposes the margin region (18) from the first edge (20) to the motive exposure area (16), then the laser exposer (12) is performing a motive exposure (16), while the diodes (15) of the light bar (13) that are located above the motive exposure area (16) are switched off so that the region between the motive exposure area (16) and the side edge (24) is fully exposed, thereafter, the light bar (13) is fully exposing the margin region (18) from the motive exposure area (16) to the second edge (22), finally, both, the light bar (13) and the laser exposer (12) remaining switched off as they are moved back from the second edge (22) to the first edge (20).

7. The method as set forth in claim 6,
characterized in that the diodes (15) of the light bar (13) are operated with reduced power only during exposure of the margin region (18) located between the motive exposure area (16) and the side edge (24).

8. An apparatus for laser exposure of a screen for use in screen printing, with a screen retaining apparatus for precisely receiving a preferably framed screen (110, 130) and with a laser exposer (122) that is mounted movable with respect to said screen (110, 130),
characterized by a light bar (112) that is also mounted movable with respect to said screen (110, 130) for exposing that region of the screen (110, 130) that is not exposed by the laser exposer (122).

9. The apparatus as set forth in claim 8,
characterized in that the light bar (112) comprises a number of LEDs (116), diodes or other light sources.

10. The apparatus as set forth in claim 8,
characterized in that the LEDs (116), diodes or other light sources are individually activatable.

11. The apparatus as set forth in claim 8,
characterized in that the light bar (112) is surrounded by a light impermeable housing (114, 134) that is configured to be light permeable toward the screen (110, 130).

12. The apparatus as set forth in claim 11,
characterized in that the housing (114, 134) extends proximate to the screen.

13. The apparatus as set forth in claim 11,
characterized in that the distance between the housing (114, 134) and the screen (110, 130) ranges between 20 μm and 80 μm, and preferably is 50 μm.

14. The apparatus as set forth in claim 8,
characterized in that the inner side of the housing (114, 134) is configured to be reflective.

15. The apparatus as set forth in claim 8,
characterized in that, on its side turned toward the screen (110, 130), the light bar (112) has a light permeable slot (120).

16. The apparatus as set forth in claim 15,
characterized in that the slot (120) extends over the entire width of the screen (110, 130) and has a span of between 0.5 mm and 2 mm, preferably of 1 mm.

17. The apparatus as set forth in claim 8,
characterized in that between 10 and 200, preferably 54, LEDs (116) or diodes are mounted in the light bar (112).

18. The apparatus as set forth in claim 8,
characterized in that each LED (116) or each diode has an outlet port of between 10° and 15°, preferably of 12°.

19. The apparatus as set forth in claim 8,
characterized in that the housing (14, 34) is configured to conically taper toward the screen (10, 30).
